(19) United States
(12) Patent Application Publication
(10) Pub. No.: US 2024/0276766 A1
(43) Pub. Date: Aug. 15, 2024

(54) DISPLAY PANEL AND DISPLAY APPARATUS

(71) Applicant: Samsung Display Co., Ltd., Yongin-Si (KR)

(72) Inventors: Taehyun Kim, Yongin-si (KR); Junhyeong Park, Yongin-si (KR); Jiyeon Seo, Yongin-si (KR)

(21) Appl. No.: 18/406,490

(22) Filed: Jan. 8, 2024

(30) Foreign Application Priority Data
Feb. 13, 2023 (KR) 10-2023-0018979

(51) Int. Cl. H10K 59/121; H10K 59/176; H10K 59/80

(52) U.S. Cl. CPC H10K 59/121; H10K 59/176; H10K 59/873

(57) ABSTRACT

The present disclosure relates to a display panel and a display apparatus. The display panel includes a substrate including a display area and a peripheral area around the display area, a display element disposed in the display area, a thin film encapsulation layer covering the display area and including a first inorganic encapsulation layer, an organic encapsulation layer, and a second inorganic encapsulation layer, and a dam unit including a plurality of dams disposed in the peripheral area. The plurality of dams include an inorganic layer, the inorganic layer is at least partially disposed on a side surface of an outermost dam among the plurality of dams, and the first inorganic encapsulation layer directly contacts the inorganic layer on a side surface of the outermost dam.

### CROSS-REFERENCE TO RELATED APPLICATION

This application is based on and claims priority under 35 U.S.C. § 119 to Korean Patent Application No. 10-2023-0018979, filed on Feb. 13, 2023, in the Korean Intellectual Property Office, the disclosure of which is incorporated by reference herein in its entirety.

### BACKGROUND

### 1. Field

One or more embodiments relate to a display panel and a display apparatus including the display panel, and more particularly, to a display panel in which a display area is extended such that an image may also be displayed in corner display areas and a display apparatus including the display panel.

### 2. Description of the Related Art

Recently, the design of display apparatuses has been diversified. For example, curved display apparatuses, foldable display apparatuses, and rollable display apparatuses have been developed. Also, the display area thereof has been expanded and the non-display area thereof has been reduced. Accordingly, various methods have been derived to design the shape of display apparatuses.

### SUMMARY

One or more embodiments include a display panel in which a display area is extended such that an image may also be displayed in a corner display area and a display apparatus including the display panel. However, these embodiments are merely examples and the scope of the disclosure is not limited thereto.

Additional aspects will be set forth in part in the description which follows and, in part, will be apparent from the description, or may be learned by practice of the presented embodiments of the disclosure.

According to one or more embodiments, a display panel includes a substrate, a display element, a thin film encapsulation layer, and a dam unit. The substrate includes a display area and a peripheral area around the display area. The display element is disposed in the display area. The thin film encapsulation layer covers the display area and includes a first inorganic encapsulation layer, an organic encapsulation layer, and a second inorganic encapsulation layer. The dam unit includes a plurality of dams disposed in the peripheral area. The plurality of dams include an inorganic layer, the inorganic layer is at least partially disposed on a side surface of an outermost dam among the plurality of dams, and the first inorganic encapsulation layer directly contacts the inorganic layer on the side surface of the outermost dam.

In an embodiment, the inorganic layer may include a protrusion tip protruding toward at least one groove of a plurality of grooves disposed between the plurality of dams.

In an embodiment, an opposite electrode of the display element may be disconnected by the protrusion tip.

In an embodiment, the inorganic layer may be disposed to extend from the side surface of the outermost dam to an upper surface of the substrate, and the first inorganic encapsulation layer may cover an edge of the inorganic layer disposed on the upper surface of the substrate.

In an embodiment, the display panel may further include an inorganic insulating layer disposed between the substrate and the display element, wherein the inorganic insulating layer extends to a portion of the peripheral area, and the inorganic layer directly contacts the inorganic insulating layer in the peripheral area.

In an embodiment, the display panel may further include a plurality of grooves disposed between the dam unit and an edge of the substrate in the peripheral area.

In an embodiment, the display area may include a front display area and a corner display area extending from a corner of the front display area, and at least two corner light emitting elements disposed in the corner display area may be connected to a pixel circuit.

In an embodiment, the corner display area may include a first corner display area and a second corner display area, and a driving circuit providing a scan signal may be disposed in the second corner display area, and a corner light emitting element disposed in the second corner display area among the at least two corner light emitting elements may be disposed to overlap the driving circuit.

In an embodiment, the substrate may further include an opening area disposed inside a front display area and a non-display area disposed between the opening area and the front display area, and the substrate may include a first opening corresponding to the opening area.

In an embodiment, the non-display area may include a plurality of grooves.

According to one or more embodiments, a display apparatus includes a cover window and a display panel. The cover window includes a flat portion and a curved portion curved at a corner of the flat portion. The display panel is disposed on a surface of the cover window and includes a substrate including a display area overlapping the flat portion and a peripheral area surrounding the display area. The display panel includes a display element disposed in the display area, a thin film encapsulation layer covering the display area and including a first inorganic encapsulation layer, an organic encapsulation layer, and a second inorganic encapsulation layer, and a dam unit including a plurality of dams disposed in the peripheral area. The plurality of dams include an inorganic layer, the inorganic layer is at least partially disposed on a side surface of an outermost dam among the plurality of dams, and the first inorganic encapsulation layer directly contacts the inorganic layer on the side surface of the outermost dam.

In an embodiment, the inorganic layer may include a protrusion tip protruding toward at least one groove of a plurality of grooves disposed between the plurality of dams.

In an embodiment, an opposite electrode of the display element may be disconnected by the protrusion tip.

In an embodiment, the inorganic layer may be disposed to extend from the side surface of the outermost dam to an upper surface of the substrate, and the first inorganic encapsulation layer may cover an edge of the inorganic layer disposed on the upper surface of the substrate.

In an embodiment, the display apparatus may further include an inorganic insulating layer disposed between the substrate and the display element, wherein the inorganic insulating layer extends to a portion of the peripheral area, and the inorganic layer directly contacts the inorganic insulating layer in the peripheral area.

In an embodiment, the display apparatus may further include a plurality of grooves disposed between the dam unit and an edge of the substrate in the peripheral area.

In an embodiment, the display area may include a front display area and a corner display area extending from a corner of the front display area, and at least two corner light emitting elements disposed in the corner display area may be connected to a pixel circuit.

In an embodiment, the corner display area may include a first corner display area and a second corner display area, and a driving circuit providing a scan signal may be disposed in the second corner display area, and a corner light emitting element disposed in the second corner display area among the at least two corner light emitting elements may be disposed to overlap the driving circuit.

In an embodiment, the display panel may further include an opening area disposed inside a front display area and a non-display area disposed between the opening area and the front display area, and a component corresponding to the opening area may be further disposed under the display panel.

In an embodiment, the non-display area may include a plurality of grooves.

### BRIEF DESCRIPTION OF THE DRAWINGS

The above and other aspects and features of certain embodiments of the disclosure will be more apparent from the following description taken in conjunction with the accompanying drawings.

FIG. 1 is a perspective view schematically illustrating a display apparatus according to an embodiment.

FIG. 2 is an exploded perspective view schematically illustrating each of a display panel and a cover window of a display apparatus according to an embodiment.

FIG. 3 is a perspective view schematically illustrating a display panel of a display apparatus according to an embodiment.

FIG. 4 is a cross-sectional view of the display apparatus taken along line I-I′ of FIG. 1.

FIG. 5 is a schematic plan view illustrating a display panel in an unfolded state, which may be included in the display apparatus of FIG. 1, according to an embodiment.

FIG. 6 is an enlarged view of region II of FIG. 5.

FIG. 7 is a cross-sectional view schematically illustrating a portion of a cross-section of a display panel according to an embodiment, which corresponds to line III-III′ of FIG. 6.

FIG. 8 is an equivalent circuit diagram of a pixel circuit that may be applied to a display panel of FIG. 5 according to an embodiment.

FIG. 9 is a cross-sectional view schematically illustrating a portion of a display panel according to an embodiment.

FIG. 10 is a cross-sectional view schematically illustrating a portion of a display panel according to an embodiment.

FIG. 11 is a cross-sectional view schematically illustrating a portion of a display panel according to an embodiment.

FIG. 12 is a schematic plan view illustrating a portion of a display panel in an unfolded state according to an embodiment.

FIG. 13 is a schematic cross-sectional view corresponding to line IV-IV′ of FIG. 12.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Throughout the disclosure, the expression “at least one of a, b and c” indicates only a, only b, only c, both a and b, both a and c, both b and c, all of a, b, and c, or variations thereof.

The disclosure may include various embodiments and modifications, and certain embodiments thereof are illustrated in the drawings and will be described herein in detail. The effects and features of the disclosure and the accomplishing methods thereof will become apparent from the embodiments described below in detail with reference to the accompanying drawings. However, the disclosure is not limited to the embodiments described below and may be embodied in various modes.

Hereinafter, embodiments will be described in detail with reference to the accompanying drawings, and in the following description, like reference numerals will denote like elements and redundant descriptions thereof will be omitted for conciseness.

It will be understood that when an element such as a layer, a region, or a plate is referred to as being “on” another element, it may be “directly on” the other element or may be “indirectly on” the other element with one or more intervening elements therebetween. Also, sizes of elements in the drawings may be exaggerated for convenience of description. In other words, because the sizes and thicknesses of elements in the drawings are arbitrarily illustrated for convenience of description, the disclosure is not limited thereto.

Also, herein, the x direction, the y direction, and the z direction are not limited to three axes of the rectangular coordinate system and may be interpreted in a broader sense. For example, the x direction, the y direction, and the z direction may be perpendicular to one another or may represent different directions that are not perpendicular to one another.

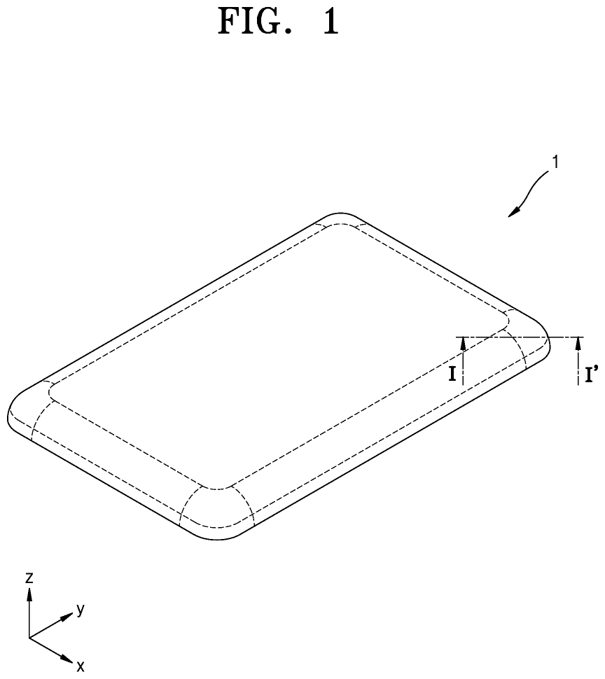

FIG. 1 is a perspective view schematically illustrating a display apparatus 1 according to an embodiment.

Referring to FIG. 1, the display apparatus 1 according to an embodiment may be an apparatus displaying a moving image or a still image and may be a portable electronic apparatus such as a mobile phone, a smart phone, a tablet personal computer (PC), a mobile communication terminal, an electronic notebook, an electronic book, a portable multimedia player (PMP), a navigation apparatus, or an ultra mobile PC (UMPC). Also, the display apparatus 1 may be an electronic apparatus providing a display screen, such as a television, a notebook computer, a monitor, a billboard, or the Internet of Things (IoT) devices. Alternatively, the display apparatus 1 may be a wearable device such as a smart watch, a watch phone, a glasses-type display, or a head-mounted display (HMD).

In an embodiment, the display apparatus 1 may have a rectangular shape with a rounded corner in the plan view. In an alternative embodiment, the display apparatus 1 may have various shapes such as other polygonal shapes such as triangular shapes and square shapes, circular shapes, and elliptical shapes. In an embodiment, when the display apparatus 1 has a polygonal shape in the plan view, a polygonal corner may be rounded. Hereinafter, for convenience of description, a case where the display apparatus 1 has a rectangular shape with a rounded corner in the plan view will be mainly described.

The display apparatus 1 may have a short side in a first direction, e.g., the x direction or the −x direction, and a long side in a second direction, e.g., the y direction or the −y direction. In an embodiment, in the display apparatus 1, the length of the side in the first direction, e.g., the x direction or the −x direction, may be equal to the length of the side in the second direction, e.g., the y direction or the −y direction. In an embodiment, the display apparatus 1 may have a long side in the first direction, e.g., the x direction or the −x direction, and a short side in the second direction, e.g., the y direction or the −y direction. Each corner where the short side in the first direction, e.g., the x direction or the −x direction, and the long side in the second direction, e.g., the y direction or the −y direction meet each other may be rounded to have a certain curvature.

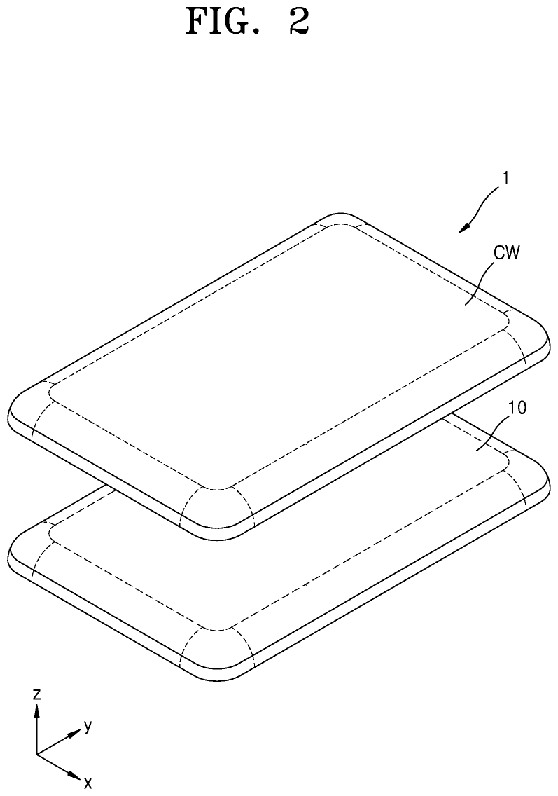

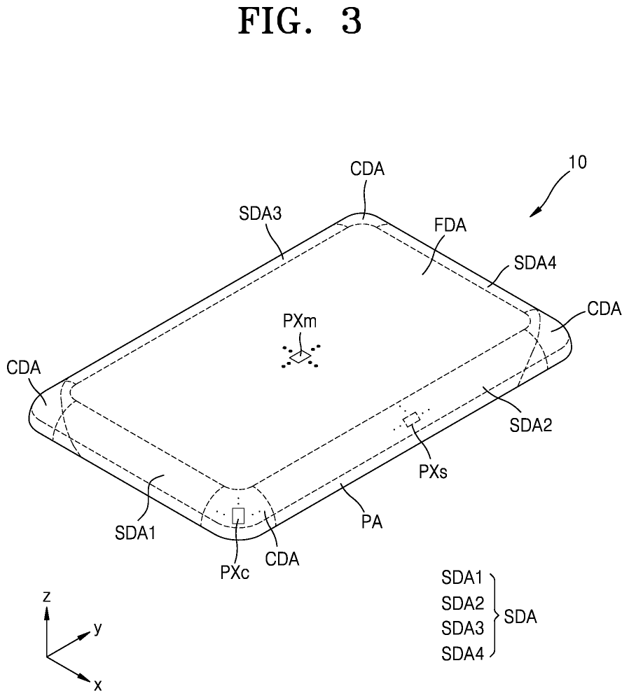

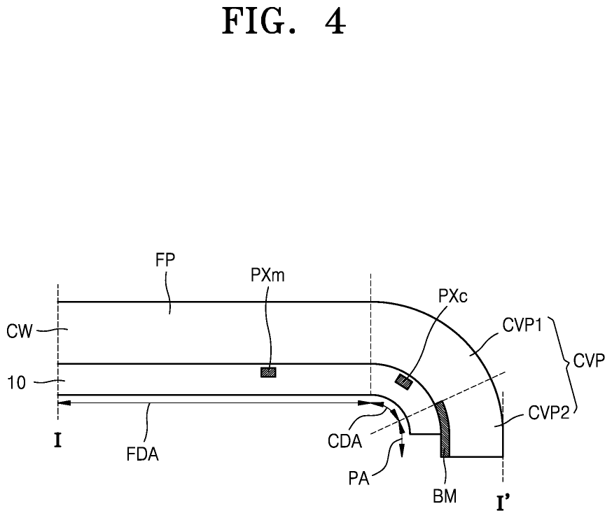

FIG. 2 is an exploded perspective view schematically illustrating each of a display panel 10 and a cover window CW of a display apparatus 1 according to an embodiment. FIG. 3 is a perspective view schematically illustrating the display panel 10 of a display apparatus 1 (e.g., see FIG. 2) according to an embodiment. FIG. 4 is a cross-sectional view of the display apparatus 1 taken along line I-I′ of FIG. 1.

Referring to FIGS. 2 to 4, the display apparatus 1 may include the display panel 10 and the cover window CW disposed over the display panel 10.

The display panel 10 may include a front display area FDA, a side display area SDA, and a corner display area CDA as a display area. The display apparatus 1 may include a peripheral area PA surrounding the display area.

The front display area FDA may be an area disposed at a front portion of the display panel 10 and may be an area formed flat without being curved. The front display area FDA may occupy the greatest ratio in the display area of the display panel 10 and accordingly may provide most images. That is, the front display area FDA may be a main display area. The front display area FDA may have a rounded rectangular shape including a short side in the x direction and a long side in the y direction, and each corner where the short side and the long side meet each other may be rounded.

At least a portion of the side display area SDA may be bent to include a curved surface and may extend outward from each side of the front display area FDA. The side display area SDA may include a first side display area SDA1, a second side display area SDA2, a third side display area SDA3, and a fourth side display area SDA4. In some embodiments, at least one of the first side display area SDA1, the second side display area SDA2, the third side display area SDA3, and the fourth side display area SDA4 may be omitted.

The first side display area SDA1 may be an area extending from a first side of the front display area FDA and curved with a certain curvature. The first side display area SDA1 may extend from a lower side of the front display area FDA. The first side display area SDA1 may be an area disposed at a lower surface of the display panel 10.

The second side display area SDA2 may be an area extending from a second side of the front display area FDA and curved with a certain curvature. The second side display area SDA2 may extend from a right side of the front display area FDA. The second side display area SDA2 may be an area disposed at a right surface of the display panel 10.

The third side display area SDA3 may be an area extending from a third side of the front display area FDA and curved with a certain curvature. The third side display area SDA3 may extend from a left side of the front display area FDA. The third side display area SDA3 may be an area disposed at a left surface of the display panel 10.

The fourth side display area SDA4 may be an area extending from a fourth side of the front display area FDA and curved with a certain curvature. The fourth side display area SDA4 may extend from an upper side of the front display area FDA. The fourth side display area SDA4 may be an area disposed at an upper surface of the display panel 10.

Each of the first to fourth side display areas SDA1, SDA2, SDA3, and SDA4 may include a curved surface bent with a certain curvature. For example, the first side display area SDA1 and the fourth side display area SDA4 have a curved surface bent around a bending axis extending in the x direction, and the second side display area SDA2 and the third side display area SDA3 may have a curved surface bent around a bending axis extending in the y direction. The respective curvatures of the first to fourth side display areas SDA1, SDA2, SDA3, and SDA4 may be equal to or different from each other.

The corner display area CDA may be an area extending from a corner of the front display area FDA and curved with a certain curvature. The corner display area CDA may be disposed between the first to fourth side display areas SDA1, SDA2, SDA3, and SDA4. For example, the corner display area CDA may be disposed between the first side display area SDA1 and the second side display area SDA2, between the first side display area SDA1 and the third side display area SDA3, between the second side display area SDA2 and the fourth side display area SDA4, and between the third side display area SDA3 and the fourth side display area SDA4.

Because the corner display area CDA is located between adjacent side display areas SDA having curved surfaces bent in different directions, the corner display area CDA may include a curved surface in which curved sub-surfaces bent in various directions are continuously connected. Also, when the respective curvatures of adjacent side display areas SDA are different from each other, the curvature of the corner display area CDA may change gradually along the edge of the display apparatus 1. For example, when the curvature of the first side display area SDA1 and the curvature of the second side display area SDA2 are different from each other, the corner display area CDA between the first side display area SDA1 and the second side display area SDA2 may have a curvature that changes gradually according to positions.

The display panel 10 may provide an image by using main pixels PXm disposed in the front display area FDA, side pixels PXs disposed in the side display area SDA, and corner pixels PXc disposed in the corner display area CDA. Because the display panel 10 provides images in the side display area SDA and the corner display area CDA in addition to the front display area FDA, the proportion of the display area in the display apparatus 1 may increase. That is, in the display apparatus 1 having the same size, the area of the peripheral area PA may decrease and the area of the display area may increase.

The peripheral area PA may be disposed to entirely or partially surround the periphery of the side display area SDA and the corner display area CDA. The peripheral area PA may be an area where an image is not provided, and various lines and driving circuits may be disposed therein. A shielding layer such as a light blocking member may be provided in the peripheral area PA such that the members disposed in the peripheral area PA are not visually recognized.

Referring to FIG. 4, the cover window CW may be disposed over a front surface of the display panel 10. Here, the ‘front surface’ of the display panel 10 may be defined as a surface facing a direction in which the display panel 10 provides an image.

The cover window CW may cover and protect the display panel 10. The cover window CW may have a high transmittance to transmit light emitted from the display panel 10 and may have a small thickness to minimize the weight of the display apparatus 1 (e.g., see FIG. 1). Also, the cover window CW may have high rigidity and hardness to protect the display panel 10 from an external impact.

The cover window CW may include a transparent material. The cover window CW may include, for example, glass or plastic. When the cover window CW includes plastic, the cover window CW may be flexible. For example, the cover window CW may include ultra-thin glass (UTG®) whose rigidity is reinforced by a method such as chemical reinforcement or thermal reinforcement. In other embodiments, the cover window CW may include tempered glass or colorless polyimide (CPI). In an embodiment, the cover window CW may have a structure in which a flexible polymer layer is disposed on one surface of a glass substrate or may include only a polymer layer.

The cover window CW may include a flat portion FP corresponding to the front display area FDA of the display panel 10 and a curved portion CVP corresponding to the side display area SDA (see FIG. 3) and corner display area CDA.

The flat portion FP of the cover window CW may be provided as a flat surface and may overlap the front display area FDA of the display panel 10. The curved portion CVP of the cover window CW may include a curved surface and in this case, may have a constant curvature or a variable curvature. The curved portion CVP may include a first curved portion CVP1 and a second curved portion CVP2. The first curved portion CVP1 may be disposed to overlap the side display area SDA and the corner display area CDA of the display panel 10. The second curved portion CVP2 may be disposed to overlap the peripheral area PA of the display panel 10. The first curved portion CVP1 may be disposed between the flat portion FP and the second curved portion CVP2.

A light blocking member BM may be disposed at a portion of the second curved portion CVP2 of the cover window CW. The light blocking member BM may cover a lower structure disposed thereunder and may be disposed to overlap the peripheral area PA of the display panel 10. The light blocking member BM may include a light blocking material. The light blocking member BM may include a resin including carbon nanotubes, or black dye (e.g., carbon black). Alternatively, the light blocking member BM may include nickel, aluminum, molybdenum, or any alloy thereof. The light blocking member BM may be applied by inkjet or attached in a film type.

The display panel 10 may be disposed under the cover window CW. The cover window CW and the display panel 10 may be coupled through an adhesive member (not illustrated). The adhesive member may include an optically clear adhesive (OCA) film or an optically clear resin (OCR) film.

The display panel 10 may provide an image by using the main pixels PXm disposed in the front display area FDA and the corner pixels PXc disposed in the corner display area CDA. A lower protection film (not illustrated) for protecting the display panel 10 may be further disposed under the display panel 10.

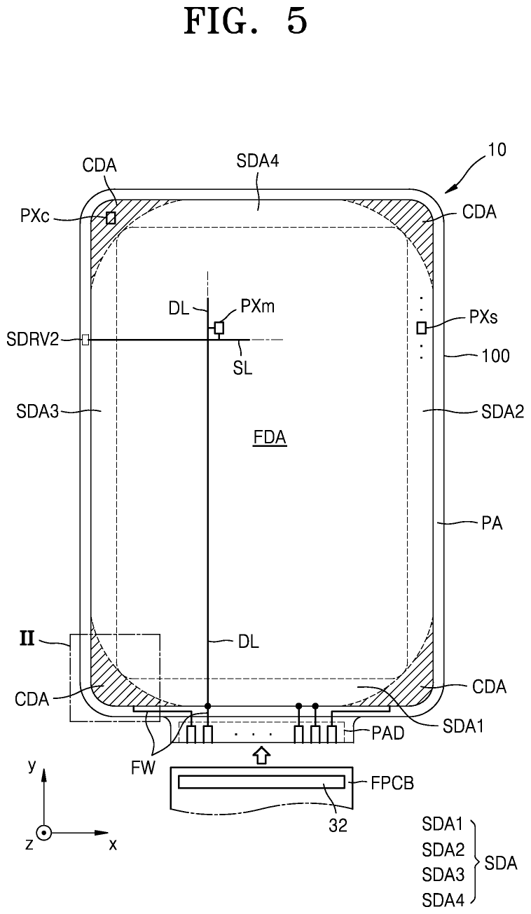

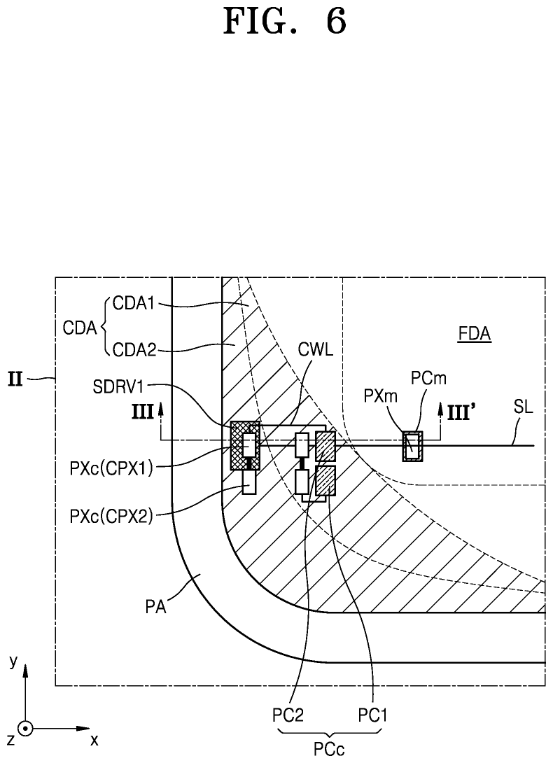

FIG. 5 is a schematic plan view illustrating a display panel 10 in an unfolded state, which may be included in the display apparatus 1 of FIG. 1, according to an embodiment. FIG. 6 is an enlarged view of region II of FIG. 5.

Referring to FIGS. 5 and 6, various components constituting the display panel 10 may be disposed over a substrate 100. The substrate 100 may include a front display area FDA, a side display area SDA, a corner display area CDA, and a peripheral area PA.

A plurality of main pixels PXm may be disposed in the front display area FDA, and a main image may be displayed by the main pixels PXm. The main pixel PXm may include a set of a plurality of subpixels. Each of subpixels may emit, for example, red, green, blue, or white light.

The side display area SDA may include a first side display area SDA1, a second side display area SDA2, a third side display area SDA3, and a fourth side display area SDA4. The side display area SDA may be disposed on the upper, lower, left, and right sides of the front display area FDA. A plurality of side pixels PXs may be disposed in the side display area SDA, and a side image may be displayed by the side pixels PXs. The side image may form an entire image together with the main image, and the side image may be an image independent from the main image.

The corner display area CDA may be disposed in an area extending from a corner of the front display area FDA. The corner display area CDA may be disposed between two side display areas SDA. A plurality of corner pixels PXc are disposed in the corner display area CDA, and a corner image may be displayed by the corner pixels PXc. The corner image may form an entire image together with the main image and the side image, and the corner image may be an image independent from the main image.

The corner display area CDA may include a first corner display area CDA1 and a second corner display area CDA2. The second corner display area CDA2 may be an area extending from the first corner display area CDA1, and the second corner display area CDA2 may be disposed nearer to an edge of the substrate 100 than the first corner display area CDA1. The first corner display area CDA1 may be disposed between the second corner display area CDA2 and the front display area FDA.

In addition to the corner pixel PXc, a driving circuit SDRV1 may be disposed in the second corner display area CDA2. The driving circuit SDRV1 may provide a scan signal for driving the main pixel PXm and the corner pixel PXc respectively disposed in the front display area FDA and the corner display area CDA. In some embodiments, the driving circuit SDRV1 may be simultaneously connected to a pixel circuit (e.g., the corner pixel circuit PCc) for driving the corner pixel PXc and a pixel circuit (e.g., the main pixel circuit PCm) for driving the main pixel PXm to provide the same scan signal thereto. In this case, a scan line SL connected to the driving circuit SDRV1 may extend from the second corner display area CDA2 to the front display area FDA. The scan line SL may extend in the x direction.

In the second corner display area CDA2, the corner pixel PXc may be disposed to overlap the driving circuit SDRV1. A corner pixel circuit PCc driving the corner pixel PXc disposed in the second corner display area CDA2 may be disposed in the first corner display area CDA1. Accordingly, pixel circuits PC1 and PC2 respectively driving the corner pixel PXc disposed in the first corner display area CDA1 and the corner pixel PXc disposed in the second corner display area CDA2 may be disposed in the first corner display area CDA1. The corner pixel PXc disposed in the second corner display area CDA2 may be driven by being connected through a connection line CWL to the pixel circuits PC1 and PC2 disposed in the first corner display area CDA1. The connection line CWL may be provided to extend in the x direction that is a direction in which the scan line SL extends.

The corner pixels PXc disposed in the corner display area CDA may include a first copy pixel CPX1 and a second copy pixel CPX2. The first copy pixel CPX1 and the second copy pixel CPX2 may be driven by one pixel circuit and may emit the same color. The first copy pixel CPX1 and the second copy pixel CPX2 may have substantially the same size. As the corner pixels PXc are provided as copy pixels, the number of pixel circuits driving the corner pixels PXc may be reduced, and because the corner pixels PXc are disposed to overlap the driving circuit SDRV1, the corner display area CDA may be extended.

The peripheral area PA may be disposed outside the side display area SDA and the corner display area CDA. Various lines, a driving circuit SDRV2, and a terminal unit PAD may be provided in the peripheral area PA.

The driving circuit SDRV2 may provide a scan signal for driving the main pixels PXm and the side pixels PXs. The driving circuit SDRV2 may be disposed on the right side of the second side display area SDA2 and/or on the left side of the third side display area SDA3 and may be connected to the scan line SL extending in the x direction.

The terminal unit PAD may be disposed under the first side display area SDA1. The terminal unit PAD may be exposed by not being covered by an insulating layer, to be connected to a display circuit board FPCB. A display driver 32 may be disposed at the display circuit board FPCB.

The display driver 32 may generate a control signal transmitted to the driving circuits SDRV1 and SDRV2. Also, the display driver 32 may generate a data signal. The generated data signal may be transmitted to the pixels PXm, PXs, and PXc through a fanout line FW and a data line DL connected to the fanout line FW.

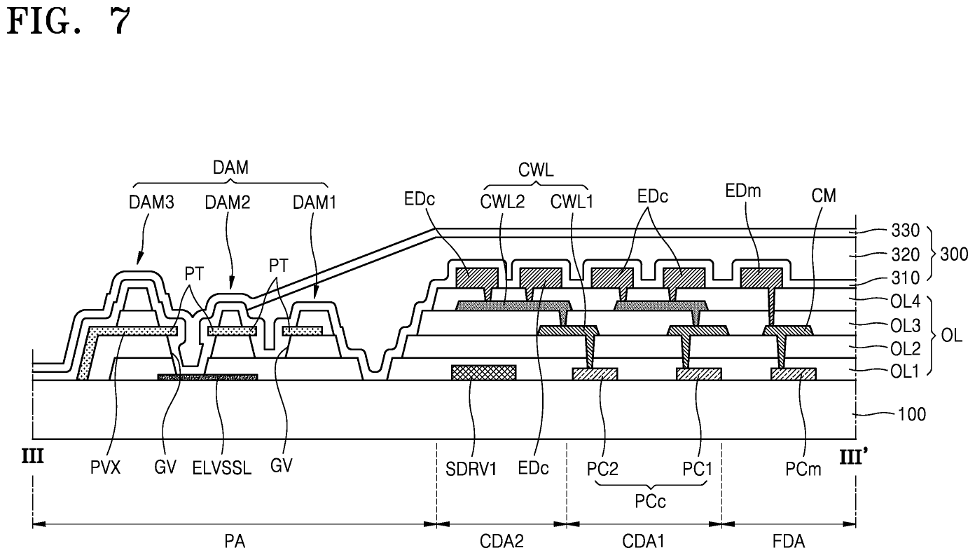

FIG. 7 is a cross-sectional view schematically illustrating a portion of a cross-section of a display panel 10 (e.g., see FIG. 5) according to an embodiment, which corresponds to line III-III′ of FIG. 6.

Referring to FIGS. 6 and 7, the display panel 10 (e.g., see FIG. 5) may include a front display area FDA, a corner display area CDA, and a peripheral area PA, and the corner display area CDA may include a first corner display area CDA1 and a second corner display area CDA2.

The substrate 100 may include an insulating material such as glass, quartz, or polymer resin. The substrate 100 may include a rigid substrate or a flexible substrate capable of bending, folding, rolling, or the like.

Pixel circuits PCm and PCc including thin film transistors, a driving circuit SDRV1 providing a scan signal to pixel circuits PCm and PCc, light emitting elements EDm and EDc respectively connected to the pixel circuits PCm and PCc and implementing pixels PXm and PXc, a thin film encapsulation layer 300 covering and protecting the light emitting elements EDm and EDc, and a dam unit DAM may be disposed over the substrate 100. The pixel circuits PCm and PCc may include a main pixel circuit PCm and a corner pixel circuit PCc, and the corner pixel circuit PCc may include a first corner pixel circuit PC1 and a second corner pixel circuit PC2. In some embodiments, the main pixel circuit PCm, the first corner pixel circuit PC1, and the second corner pixel circuit PC2 may be provided as the same pixel circuit. In other embodiments, at least some of the main pixel circuit PCm, the first corner pixel circuit PC1, and the second corner pixel circuit PC2 may be modified or provided as different pixel circuits.

An organic insulating layer OL may be disposed between the pixel circuits PCm and PCc and the light emitting elements EDm and EDc, sometimes called the main light emitting element EDm and the corner light emitting element EDc. The organic insulating layer OL may include a stack of a plurality of organic insulating layers. In some embodiments, the organic insulating layer OL may include a stack of a first organic insulating layer OL1, a second organic insulating layer OL2, a third organic insulating layer OL3, and a fourth organic insulating layer OL4.

The main pixel circuit PCm and the main light emitting element EDm connected thereto may be disposed in the front display area FDA of the display panel 10. An emission area of the main light emitting element EDm may correspond to the main pixel PXm, e.g., see FIG. 6. The main pixel circuit PCm may include at least one thin film transistor and may control the light emission of the main light emitting element EDm. The main light emitting element EDm may be connected to the main pixel circuit PCm through a connection electrode CM. The main light emitting element EDm may at least partially overlap the main pixel circuit PCm.

A first corner pixel circuit PC1 and a corner light emitting element EDc connected thereto may be disposed in the first corner display area CDA1 of the display panel 10. An emission area of the corner light emitting element EDc may correspond to the corner pixel PXc, e.g., see FIG. 6. The first corner pixel circuit PC1 may include at least one thin film transistor and may control the light emission of at least two corner light emitting elements EDc. In an embodiment, two corner light emitting elements EDc may be connected to one first corner pixel circuit PC1 to simultaneously emit light. In this case, the two corner light emitting elements EDc may implement copy pixels.

A second corner pixel circuit PC2 connected to the corner light emitting element EDc disposed in the second corner display area CDA2 may be disposed in the first corner display area CDA1. The second corner pixel circuit PC2 may include at least one thin film transistor and may control the light emission of at least two corner light emitting elements EDc. In an embodiment, two corner light emitting elements EDc may be connected to one second corner pixel circuit PC2 to simultaneously emit light. In this case, the two corner light emitting elements EDc may implement copy pixels.

The second corner pixel circuit PC2 may be connected to the corner light emitting element EDc disposed in the second corner display area CDA2 by a connection line CWL. The connection line CWL may include a first connection line CWL1 and a second connection line CWL2 disposed on different layers. The second corner pixel circuit PC2 may be connected to the corner light emitting element EDc only by the first connection line CWL1, may be connected to the corner light emitting element EDc only by the second connection line CWL2, or may be connected to the corner light emitting element EDc by the first connection line CWL1 and the second connection line CWL2; that is, the connection relationship therebetween may be variously modified.

The driving circuit SDRV1 may be disposed in the second corner display area CDA2 of the display panel 10. The driving circuit SDRV1 may include at least one thin film transistor and may provide a scan signal to the corner pixel circuit PCc and the main pixel circuit PCm disposed in the corner display area CDA (specifically, the first corner display area CDA1) and the front display area FDA. An emission control driving circuit (not illustrated) providing an emission control signal in addition to a scan signal may be further disposed in the second corner display area CDA2. The driving circuit SDRV1 and the emission control driving circuit may overlap the corner light emitting element EDc.

The emission areas of the corner light emitting elements EDc disposed in the first corner display area CDA1 and the second corner display area CDA2 may represent corner pixels PXc, and the corner pixels PXc may be disposed in the same pixel arrangement in the first corner display area CDA1 and the second corner display area CDA2.

The main light emitting element EDm and the corner light emitting element EDc may be covered by the thin film encapsulation layer 300. In some embodiments, the thin film encapsulation layer 300 may include at least one inorganic encapsulation layer and at least one organic encapsulation layer. In an embodiment, the thin film encapsulation layer 300 may cover a display area and may include first and second inorganic encapsulation layers 310 and 330 and an organic encapsulation layer 320 therebetween.

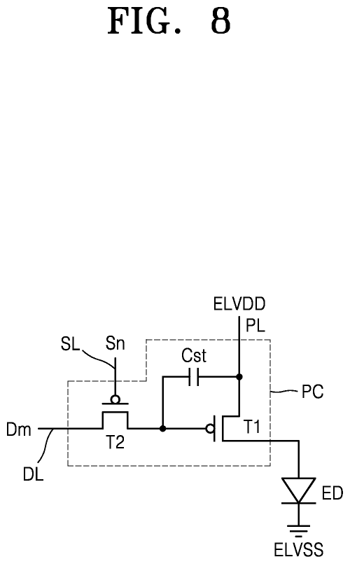

The dam unit DAM and a common voltage line ELVSSL configured to transmit a common voltage ELVSS, e.g., see FIG. 8, to a light emitting element may be disposed in the peripheral area PA of the display panel 10. The dam unit DAM may be provided to overlap the common voltage line ELVSSL. The dam unit DAM may prevent the flow of the organic encapsulation layer 320 of the thin film encapsulation layer 300 and may prevent the penetration of external moisture.

The dam unit DAM may include a plurality of dams. The dam unit DAM may include a first dam DAM1, a second dam DAM2, and a third dam DAM3. A groove GV may be formed in a depth direction between the plurality of dams. The plurality of dams may include a stack of a plurality of organic insulating layers OL. Each of the first dam DAM1 and the second dam DAM2 may include a stack of the first organic insulating layer OL1, the second organic insulating layer OL2, and the third organic insulating layer OL3.

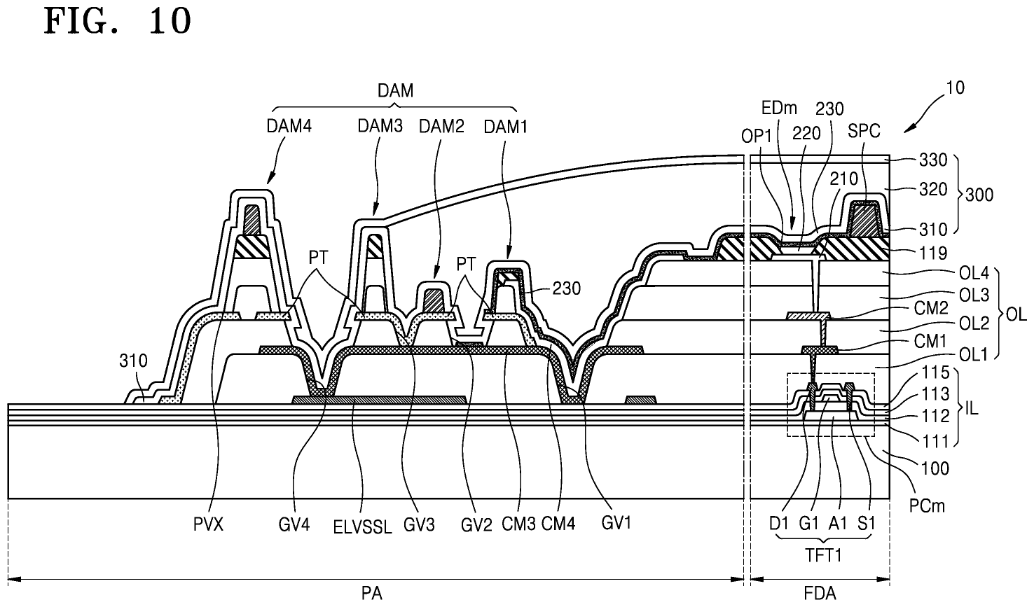

In the present embodiment, each of the first dam DAM1 and the second dam DAM2 may further include an inorganic layer PVX disposed between the second organic insulating layer OL2 and the third organic insulating layer OL3. The inorganic layer PVX may include a protrusion tip PT protruding toward the center of the groove GV disposed between the first dam DAM1 and the second dam DAM2. As an opposite electrode or an organic layer included in a light emitting element is disconnected by the protrusion tip PT, a tolerance margin required when depositing the opposite electrode (e.g., the opposite electrode 230 of FIG. 10) or the organic layer may be reduced and thus the area of the peripheral area PA may be remarkably reduced.

In the present embodiment, the third dam DAM3 may include a stack of the first organic insulating layer OL1, the second organic insulating layer OL2, the third organic insulating layer OL3, and the fourth organic insulating layer OL4. The third dam DAM3 may further include the inorganic layer PVX disposed between the second organic insulating layer OL2 and the third organic insulating layer OL3. The inorganic layer PVX may cover the side surface of the third dam DAM3 adjacent to the edge of the substrate 100. That is, the inorganic layer PVX may be provided to cover one side of the second organic insulating layer OL2 that is a second layer of the third dam DAM3. The inorganic layer PVX may be disposed to extend from one side of the second organic insulating layer OL2 (or from a side surface of the fourth DAM3 as the outermost dam) to the upper surface of the substrate 100. Accordingly, the first inorganic encapsulation layer 310 of the thin film encapsulation layer 300 may contact the inorganic layer PVX on the side surface of the third dam DAM3. The second inorganic encapsulation layer 330 may also contact the first inorganic encapsulation layer 310 on the side surface of the third dam DAM3.

Moreover, the first inorganic encapsulation layer 310 may clad the edge of the inorganic layer PVX on the upper surface of the substrate 100, and the second inorganic encapsulation layer 330 may clad the edge of the first inorganic encapsulation layer 310 on the upper surface of the substrate 100. By this structure, the penetration of external air into the display area may be effectively prevented. Also, because the first inorganic encapsulation layer 310, the second inorganic encapsulation layer 330, and the inorganic layer PVX contact each other on the side surface of the third dam DAM3, the area of the peripheral area PA may be remarkably reduced. As the area of the peripheral area PA decreases, the area of the second corner display area CDA2 may increase, which may mean that the area of the display area of the display apparatus 1 (e.g., see FIG. 2) increases.

FIG. 8 is an equivalent circuit diagram of a pixel circuit PC that may be applied to a display panel 10 of FIG. 5 according to an embodiment.

Referring to FIG. 8, the pixel circuit PC may be connected to a light emitting element ED to implement light emission of subpixels. The pixel circuit PC may include a driving thin film transistor T1, a switching thin film transistor T2, and a storage capacitor Cst. The switching thin film transistor T2 may be connected to a scan line SL and a data line DL and may be configured to transmit a data signal Dm input through the data line DL to the driving thin film transistor T1 according to a scan signal Sn input through the scan line SL.

The storage capacitor Cst may be connected to the switching thin film transistor T2 and a driving voltage line PL and may store a voltage corresponding to the difference between a voltage received from the switching thin film transistor T2 and a driving voltage ELVDD supplied to the driving voltage line PL.

The driving thin film transistor T1 may be connected to the driving voltage line PL and the storage capacitor Cst and may control a driving current flowing from the driving voltage line PL through the light emitting element ED in response to a voltage stored in the storage capacitor Cst. The light emitting element ED may emit light with a certain brightness according to the driving current.

FIG. 8 illustrates a case where the pixel circuit PC includes two thin film transistors and one storage capacitor; however, the disclosure is not limited thereto. The pixel circuit PC may be variously modified, such as including 3 to 9 thin film transistors and 1 to 2 capacitors. The pixel circuit PC may be similarly applied to the main pixel circuit PCm and the corner pixel circuit PCc shown in FIG. 7, and various modifications may be made therein, such as some configuration thereof being modified. For example, the capacitance of a storage capacitor included in the main pixel circuit PCm and the capacitance of a storage capacitor included in the corner pixel circuit PCc may be different from each other. Alternatively, various modifications may be made therein, such as the number of thin film transistors included in the main pixel circuit PCm and the number of thin film transistors included in the corner pixel circuit PCc being different from each other.

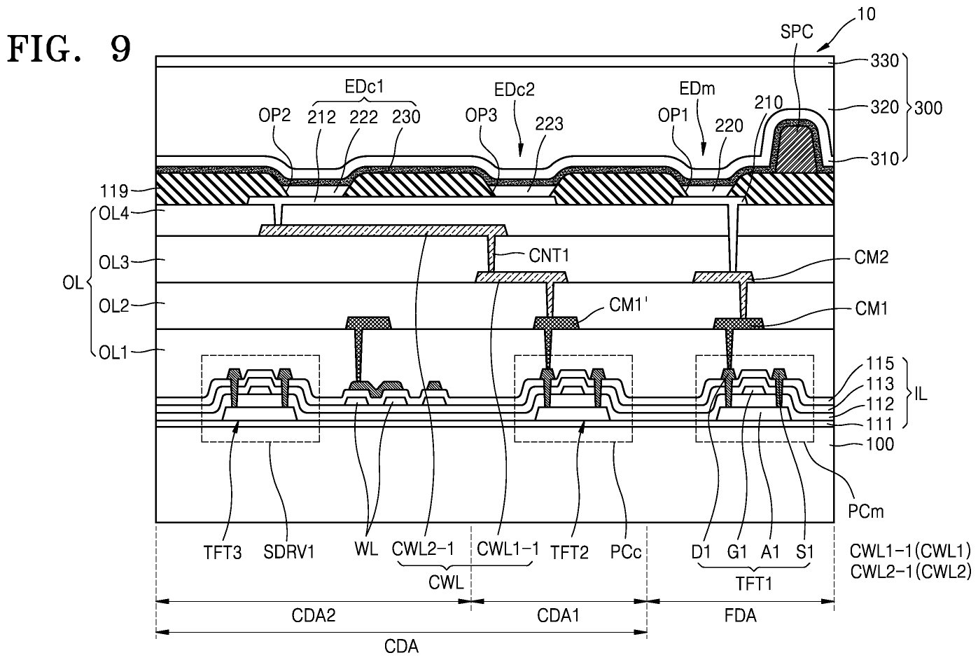

Hereinafter, a structure in which the components included in the display panel 10 are stacked will be described in more detail with reference to FIGS. 9 and 10.

FIG. 9 is a cross-sectional view schematically illustrating a portion of a display panel 10 according to an embodiment. Particularly, FIG. 9 illustrates a portion of a front display area FDA and a corner display area CDA of the display panel 10.

Referring to FIG. 9, a main light emitting element EDm and a main pixel circuit PCm connected to the main light emitting element EDm may be disposed in the front display area FDA. Corner light emitting elements EDc1 and EDc2 may be disposed as corner light emitting elements in the corner display area CDA. The corner light emitting elements EDc1 and EDc2 may include a first corner light emitting element EDc1 and a second corner light emitting element EDc2 connected to each other. The main light emitting element EDm and the corner light emitting elements EDc1 and EDc2 may be provided as organic light emitting diodes.

A corner pixel circuit PCc connected to the corner light emitting elements EDc1 and EDc2 may be disposed in a first corner display area CDA1 of the corner display area CDA. A driving circuit SDRV1 providing a driving signal such as a scan signal to the pixel circuits PCm and PCc may be disposed in a second corner display area CDA2. The main pixel circuit PCm may include a first thin film transistor TFT1, the corner pixel circuit PCc may include a second thin film transistor TFT2, and the driving circuit SDRV1 may include a third thin film transistor TFT3.

Moreover, a connection line CWL connecting the corner pixel circuit PCc to the corner light emitting elements EDc1 and EDc2 may be disposed in the first corner display area CDA1 and the second corner display area CDA2. The connection line CWL may include a first connection line CWL1 and a second connection line CWL2 disposed on different layers.

A substrate 100 may include an insulating material such as glass, quartz, or polymer resin. The substrate 100 may include a rigid substrate or a flexible substrate capable of bending, folding, rolling, or the like.

A buffer layer 111 may be located over the substrate 100 to reduce or block the penetration of foreign materials, moisture, or external air from under the substrate 100 and may provide a flat surface over the substrate 100. The buffer layer 111 may include an inorganic material such as oxide or nitride, an organic material, or an organic/inorganic composite and may include a single-layer or multiple-layer structure of an inorganic material and an organic material. A barrier layer (not illustrated) for blocking the penetration of external air may be further included between the substrate 100 and the buffer layer 111. In some embodiments, the buffer layer 111 may include silicon oxide (SiO₂) or silicon nitride (SiNₓ).

The first thin film transistor TFT1, the second thin film transistor TFT2, and the third thin film transistor TFT3 may be disposed over the buffer layer 111. The first thin film transistor TFT1 may include a first semiconductor layer A1, a first gate electrode G1, a first source electrode S1, and a first drain electrode D1. The first thin film transistor TFT1 may be connected to the main light emitting element EDm to drive the main light emitting element EDm. The second thin film transistor TFT2 may be connected to the corner light emitting elements EDc1 and EDc2 to drive the corner light emitting elements EDc1 and EDc2. The third thin film transistor TFT3 may be a thin film transistor included in the driving circuit SDRV1 and may provide a driving signal such as a scan signal.

The second thin film transistor TFT2 and the third thin film transistor TFT3 may have a similar structure to the first thin film transistor TFT1, and thus, the description of the second thin film transistor TFT2 and the third thin film transistor TFT3 may be replaced with the description of the first thin film transistor TFT1. As set forth above, the first thin film transistor TFT1 may include the first semiconductor layer A1, the first gate electrode G1, the first source electrode S1, and the first drain electrode D1.

The first semiconductor layer A1 may be disposed over the buffer layer 111 and may include polysilicon. In other embodiments, the first semiconductor layer A1 may include amorphous silicon. In other embodiments, the first semiconductor layer A1 may include an oxide of at least one of indium (In), gallium (Ga), stannum (Sn), zirconium (Zr), vanadium (V), hafnium (Hf), cadmium (Cd), germanium (Ge), chromium (Cr), titanium (Ti), and zinc (Zn). The first semiconductor layer A1 may include a channel area and a source area and a drain area that are doped with dopants.

A first gate insulating layer 112 may be provided to cover the first semiconductor layer A1. The first gate insulating layer 112 may include an inorganic insulating material such as silicon oxide (SiO₂), silicon nitride (SiNₓ), silicon oxynitride (SiOₓN_{y}), aluminum oxide (Al₂O₃), titanium oxide (TiO₂), tantalum oxide (Ta₂O₅), or hafnium oxide (HfO₂). The first gate insulating layer 112 may include a single layer or multiple layers including the above inorganic insulating material.

The first gate electrode G1 may be disposed over the first gate insulating layer 112 to overlap the first semiconductor layer A1. The first gate electrode G1 may include molybdenum (Mo), aluminum (Al), copper (Cu), titanium (Ti), or the like and may include a single layer or multiple layers. For example, the first gate electrode G1 may include a single Mo layer.

A second gate insulating layer 113 may be provided to cover the first gate electrode G1. The second gate insulating layer 113 may include an inorganic insulating material such as silicon oxide (SiO₂), silicon nitride (SiNₓ), silicon oxynitride (SiOₓN_{y}), aluminum oxide (Al₂O₃), titanium oxide (TiO₂), tantalum oxide (Ta₂O₅), hafnium oxide (HfO₂), zinc oxide (ZnO), or zinc peroxide (ZnO₂). The second gate insulating layer 113 may include a single layer or multiple layers including the above inorganic insulating material.

Lines WL and capacitor electrodes (not illustrated) may be disposed over the second gate insulating layer 113. Some of the lines WL disposed in the second corner display area CDA2 may be connected to the driving circuit SDRV1 to transmit driving signals. The lines WL may include a conductive material such as aluminum (Al), platinum (Pt), palladium (Pd), silver (Ag), magnesium (Mg), gold (Au), nickel (Ni), neodymium (Nd), iridium (Ir), chromium (Cr), calcium (Ca), molybdenum (Mo), titanium (Ti), tungsten (W), and/or copper (Cu) and may include a single layer or multiple layers including the above conductive material.

An interlayer insulating layer 115 may be formed over the second gate insulating layer 113 to cover the lines WL. The interlayer insulating layer 115 may include an inorganic insulating material such as silicon oxide (SiO₂), silicon nitride (SiNₓ), silicon oxynitride (SiOₓN_{y}), aluminum oxide (Al₂O₃), titanium oxide (TiO₂), tantalum oxide (Ta₂O₅), or hafnium oxide (HfO₂). The interlayer insulating layer 115 may include a single layer or multiple layers including the above inorganic insulating material.

The first source electrode S1 and the first drain electrode D1 may be disposed over the interlayer insulating layer 115. The first source electrode S1 and the first drain electrode D1 may include a conductive material including molybdenum (Mo), aluminum (Al), copper (Cu), titanium (Ti), or the like and may include a single layer or multiple layers including the above conductive material. For example, the first source electrode S1 and the first drain electrode D1 may include a multiple-layer structure of Ti/Al/Ti.

A first organic insulating layer OL1 may be disposed over the interlayer insulating layer 115 to cover the first source electrode S1 and the first drain electrode D1. First connection electrodes CM1 and CM1′ respectively connected to the pixel circuits PCm and PCc may be disposed over the first organic insulating layer OL1. The first connection electrodes CM1 and CM1′ may include a conductive material including molybdenum (Mo), aluminum (Al), copper (Cu), titanium (Ti), or the like and may include a single layer or multiple layers including the above conductive material.

The buffer layer 111, the first gate insulating layer 112, the second gate insulating layer 113, and the interlayer insulating layer 115 may be collectively referred to as an inorganic insulating layer IL. The inorganic insulating layer IL may be disposed between the substrate 100 and the light emitting elements EDm, EDc1, and EDc2 or between the substrate 100 and the organic insulating layer OL.

A second organic insulating layer OL2 covering the first connection electrodes CM1 and CM1′ may be disposed over the first organic insulating layer OL1. First connection lines CWL1 and a second connection electrode CM2 may be disposed over the second organic insulating layer OL2. The first connection lines CWL1 may be connected to the first connection electrode CM1′ connected to the corner pixel circuit PCc, and the second connection electrode CM2 may be connected to the first connection electrode CM1 connected to the main pixel circuit PCm.

The first connection lines CWL1 and the second connection electrode CM2 may include a conductive material including molybdenum (Mo), aluminum (Al), copper (Cu), titanium (Ti), or the like and may include a single layer or multiple layers including the above conductive material. Alternatively, the first connection lines CWL1 and the second connection electrode CM2 may include a transparent conductive material. For example, the first connection lines CWL1 and the second connection electrode CM2 may include a transparent conducting oxide (TCO). The first connection lines CWL1 and the second connection electrode CM2 may include a conductive oxide such as indium tin oxide (ITO), indium zinc oxide (IZO), zinc oxide (ZnO), indium oxide (In₂O₃), indium gallium oxide (IGO), or aluminum zinc oxide (AZO).

A third organic insulating layer OL3 covering the first connection lines CWL1 may be disposed over the second organic insulating layer OL2. Second connection lines CWL2 may be disposed over the third organic insulating layer OL3. Among the second connection lines CWL2, a (2-1)th connection line CWL2-1 may be connected to a (1-1)th connection line CWL1-1 that is one of the first connection lines CWL1 through a contact hole CNT1 passing through the third organic insulating layer OL3.

The second connection lines CWL2 may include a conductive material including molybdenum (Mo), aluminum (Al), copper (Cu), titanium (Ti), or the like and may include a single layer or multiple layers including the above conductive material. Alternatively, the second connection lines CWL2 may include a transparent conductive material. For example, the second connection lines CWL2 may include a transparent conductive oxide (TCO). The second connection lines CWL2 may include a conductive oxide such as indium tin oxide (ITO), indium zinc oxide (IZO), zinc oxide (ZnO), indium oxide (In₂O₃), indium gallium oxide (IGO), or aluminum zinc oxide (AZO).

At least one of the first connection lines CWL1 and the second connection lines CWL2 may be disposed to extend from the first corner display area CDA1 to the second corner display area CDA2. Accordingly, at least one of the first connection lines CWL1 and the second connection lines CWL2 may overlap the driving circuit SDRV1.

A fourth organic insulating layer OL4 may be disposed over the third organic insulating layer OL3 to cover the second connection lines CWL2. The fourth organic insulating layer OL4 may have a flat upper surface such that a first pixel electrode 210 and a second pixel electrode 212 disposed thereover may be formed flat.

The first organic insulating layer OL1, the second organic insulating layer OL2, the third organic insulating layer OL3, and the fourth organic insulating layer OL4 may each include a general-purpose polymer such as polystyrene (PS), benzocyclobutene (BCB), hexamethyldisiloxane (HMDSO), polymethylmethacrylate (PMMA), or, a polymer derivative having a phenolic group, an acrylic-based polymer, an imide-based polymer, an aryl ether-based polymer, an amide-based polymer (such as polyimide), a fluorine-based polymer, a p-xylene-based polymer, or a vinyl alcohol-based polymer. The first organic insulating layer OL1, the second organic insulating layer OL2, the third organic insulating layer OL3, and the fourth organic insulating layer OL4 may be variously modified, such as including the same material or different materials.

The light emitting elements EDm, EDc1, and EDc2 may be disposed over the fourth organic insulating layer OL4. The main light emitting element EDm may include the first pixel electrode 210, a first emission layer 220, and an opposite electrode 230. The first corner light emitting element EDc1 may include the second pixel electrode 212, a second emission layer 222, and the opposite electrode 230, and the second corner light emitting element EDc2 may include the second pixel electrode 212, a third emission layer 223, and the opposite electrode 230. The first corner light emitting element EDc1 and the second corner light emitting element EDc2 may share the second pixel electrode 212.

The first pixel electrode 210 and the second pixel electrode 212 may include a conductive oxide such as indium tin oxide (ITO), indium zinc oxide (IZO), zinc oxide (ZnO), indium oxide (In₂O₃), indium gallium oxide (IGO), or aluminum zinc oxide (AZO). The first pixel electrode 210 and the second pixel electrode 212 may include a reflection layer including silver (Ag), magnesium (Mg), aluminum (Al), platinum (Pt), palladium (Pd), gold (Au), nickel (Ni), neodymium (Nd), iridium (Ir), chromium (Cr), or any compound thereof. For example, the first pixel electrode 210 and the second pixel electrode 212 may have a structure including layers formed of ITO, IZO, ZnO, or In₂O₃ over/under the reflection layer. In this case, the first pixel electrode 210 and the second pixel electrode 212 may have a stack structure of ITO/Ag/ITO.

A pixel definition layer 119 may be disposed over the fourth organic insulating layer OL4 and may define an emission area of the light emitting elements EDm, EDc1, and EDc2. The pixel definition layer 119 may cover an edge of the first pixel electrode 210 and may include a first opening OP1 extending to and exposing a center portion of the first pixel electrode 210. The size and shape of the emission area of the main light emitting element EDm may be defined by the first opening OP1.

The pixel definition layer 119 may cover an edge of the second pixel electrode 212 and may include a second opening OP2 and a third opening OP3 extending to and exposing two areas of a center portion of the second pixel electrode 212. The second opening OP2 may define an emission area of the first corner light emitting element EDc1, and the third opening OP3 may define an emission area of the second corner light emitting element EDc2. In some embodiments, the second opening OP2 and the third opening OP3 may have the same size and shape.

The pixel definition layer 119 may increase the distance between the edge of the pixel electrodes 210 and 212 and the opposite electrode 230 disposed over the pixel electrodes 210 and 212 to prevent an arc or the like from occurring at the edge of the pixel electrodes 210 and 212. The pixel definition layer 119 may be formed of an organic insulating material such as polyimide, polyamide, acrylic resin, benzocyclobutene, hexamethyldisiloxane (HMDSO), or phenol resin by spin coating or the like.

A spacer SPC may be disposed on an upper surface of the pixel definition layer 119. The spacer SPC may be provided to prevent mask stamping during a process thereof. The spacer SPC may be formed of an organic insulating material such as polyimide, polyamide, acrylic resin, benzocyclobutene, hexamethyldisiloxane (HMDSO), or phenol resin by spin coating or the like.

The first emission layer 220, the second emission layer 222, and the third emission layer 223 may be respectively disposed inside the first opening OP1, the second opening OP2, and the third opening OP3 of the pixel definition layer 119. The first emission layer 220, the second emission layer 222, and the third emission layer 223 may each include a high molecular weight material or a low molecular weight material and may each emit red, green, blue, or white light. In an embodiment, the second emission layer 222 and the third emission layer 223 may include the same material and may emit light of the same color.

An organic functional layer (not illustrated) may be disposed over and/or under the first emission layer 220, the second emission layer 222, and the third emission layer 223. The organic functional layer of the first emission layer 220, the second emission layer 222, and the third emission layer 223 may include a hole injection layer (HIL), a hole transport layer (HTL), an electron transport layer (ETL), and/or an electron injection layer (EIL). The organic functional layer may be integrally formed to correspond to the light emitting elements EDm, EDc1, and EDc2 included in the front display area FDA and the corner display area CDA.

An opposite electrode 230 may be disposed over the first emission layer 220, the second emission layer 222, and the third emission layer 223. The opposite electrode 230 may include a conductive material having a low work function. For example, the opposite electrode 230 may include a (semi)transparent layer including silver (Ag), magnesium (Mg), aluminum (Al), platinum (Pt), palladium (Pd), gold (Au), nickel (Ni), neodymium (Nd), iridium (Ir), chromium (Cr), lithium (Li), calcium (Ca), or any alloy thereof. Alternatively, the opposite electrode 230 may further include a layer such as ITO, IZO, ZnO, or In₂O₃ over the (semi)transparent layer including the above conductive material. The opposite electrode 230 may be integrally formed to correspond to the light emitting elements EDm, EDc1, and EDc2 included in the front display area FDA and the corner display area CDA included in a main display area and a component area.

An upper layer (not illustrated) including an organic material may be formed over the opposite electrode 230. The upper layer may be provided to protect the opposite electrode 230 and improve light extraction efficiency. The upper layer may include an organic material having a higher refractive index than the opposite electrode 230. Alternatively, the upper layer may include a stack of layers having different refractive indexes. For example, the upper layer may include a stack of a high refractive index layer/a low refractive index layer/a high refractive index layer. In this case, the refractive index of the high refractive index layer may be about 1.7 or more, and the refractive index of the low refractive index layer may be about 1.3 or less.

The upper layer may additionally include LiF. Alternatively, the upper layer may additionally include an inorganic insulating material such as silicon oxide (SiO₂) or silicon nitride (SiNₓ).

The light emitting elements EDm, EDc1, and EDc2 may be covered and protected by a thin film encapsulation layer 300. The thin film encapsulation layer 300 may include at least one organic encapsulation layer and at least one inorganic encapsulation layer. FIG. 9 illustrates that the thin film encapsulation layer 300 includes first and second inorganic encapsulation layers 310 and 330 and an organic encapsulation layer 320 disposed therebetween. In other embodiments, the number of organic encapsulation layers, the number of inorganic encapsulation layers, and the stacking order thereof may be modified.

The first inorganic encapsulation layer 310 and the second inorganic encapsulation layer 330 may each include one or more inorganic insulating materials such as silicon oxide (SiO₂), silicon nitride (SiNₓ), or silicon oxynitride (SiOₓN_{y}) and may be formed by chemical vapor deposition (CVD) or the like. The organic encapsulation layer 320 may include a polymer-based material. The polymer-based material may include acryl-based resin, epoxy-based resin, polyimide, polyethylene, and the like.

In the present embodiment, the corner pixel circuit PCc may be disposed in the first corner display area CDA1, and one corner pixel circuit PCc may be connected to at least two corner light emitting elements EDc1 and EDc2. For example, one corner pixel circuit PCc may be connected to the first corner light emitting element EDc1 and the second corner light emitting element EDc2. It is illustrated that one corner pixel circuit PCc is connected to two corner light emitting elements EDc1 and EDc2 (e.g., two organic light emitting diodes); however, the disclosure is not limited thereto. Various modifications may be made therein, such as one corner pixel circuit PCc being connected to three or four corner light emitting elements EDc1 and EDc2 (e.g., three or four organic light emitting diodes).

The corner pixel circuit PCc may be connected to the corner light emitting elements EDc1 and EDc2 through the connection line CWL extending from the first corner display area CDA1 to the second corner display area CDA2. The connection line CWL may include the first connection line CWL1 disposed over the second organic insulating layer OL2 and the second connection line CWL2 disposed over the third organic insulating layer OL3.

Among the second connection lines CWL2, the (2-1)th connection line CWL2-1 may be connected to the (1-1)th connection line CWL1-1 through the contact hole CNT1 passing through the third organic insulating layer OL3. As the (1-1)th connection line CWL1-1 is connected through a contact hole to the first connection electrode CM1′ connected to the corner pixel circuit PCc and the (2-1)th connection line CWL2-1 is connected through a contact hole to the second pixel electrode 212, the corner pixel circuit PCc may be connected to the corner light emitting elements EDc1 and EDc2.

FIG. 10 is a cross-sectional view schematically illustrating a portion of a display panel 10 according to an embodiment. Particularly, FIG. 10 illustrates a portion of a front display area FDA and a peripheral area PA of a display panel 10. In FIG. 10, like reference numerals as those in FIG. 9 denote like members, and thus, redundant descriptions thereof will be omitted for conciseness.

Referring to FIG. 10, a dam unit DAM including a plurality of dams may be disposed in the peripheral area PA. When an organic encapsulation layer 320 of a thin film encapsulation layer 300 is formed, the dam unit DAM may be a member for blocking the flow of an organic material forming the organic encapsulation layer 320.

The dam unit DAM may include a first dam DAM1, a second dam DAM2, a third dam DAM3, and a fourth dam DAM4, sometimes called a plurality of dams. The first dam DAM1, the second dam DAM2, the third dam DAM3, and the fourth dam DAM4 may include a stack of a plurality of organic layers and an inorganic layer PVX.

The inorganic layer PVX may include an inorganic insulating material. For example, the inorganic layer PVX may include a single layer or multiple layers including an inorganic insulating material such as silicon oxide (SiO₂) or silicon nitride (SiNₓ). Alternatively, the inorganic layer PVX may include a metal material. For example, the inorganic layer PVX may include a metal material such as molybdenum (Mo), aluminum (Al), copper (Cu), or titanium (Ti) and may include a single layer or multiple layers including the above metal material. When the inorganic layer PVX includes a metal material, the inorganic layer PVX may be simultaneously formed of the same material as the second connection electrode CM2.

The first dam DAM1 may be a dam disposed closest to the display area, e.g., the front display area FDA, and may include a stack of a first layer including the same material as the first organic insulating layer OL1, a second layer including the same material as the second organic insulating layer OL2, a third layer including the inorganic layer PVX, a fourth layer including the same material as the third organic insulating layer OL3, and a fifth layer including the same material as the pixel definition layer 119.

The first dam DAM1 may be provided apart from the organic insulating layer OL extending from the display area. A first groove GV1 may be formed between the first dam DAM1 and the organic insulating layer OL. That is, a first groove GV1 extending to and exposing an upper surface of the inorganic insulating layer IL may be formed between the dam unit DAM and the organic insulating layer OL. As the first groove GV1 is formed, external air that may penetrate into the display area may be blocked.

The second dam DAM2 may be disposed outside the first dam DAM1 and may include a stack of a first layer including the same material as the first organic insulating layer OL1, a second layer including the same material as the second organic insulating layer OL2, a third layer including the inorganic layer PVX, and a fourth layer including the same material as the spacer SPC. The height of the second dam DAM2 may be less than the height of the first dam DAM1.

The first dam DAM1 and the second dam DAM2 may share the first layer. A second groove GV2 may be disposed between the second layer of the first dam DAM1 and the second layer of the second dam DAM2, and the second layer of the first dam DAM1 and the second layer of the second dam DAM2 may be disposed apart from each other. The inorganic layer PVX may include a protrusion tip PT protruding toward the second groove GV2 between the first dam DAM1 and the second dam DAM2. The opposite electrode 230 may be disconnected by the protrusion tip PT. As the opposite electrode 230 included in the light emitting element is disconnected by the protrusion tip PT, a tolerance margin required when depositing the thin film encapsulation layer 300 may be reduced and thus the area of the peripheral area PA may be remarkably reduced.

The third dam DAM3 may be disposed outside the second dam DAM2 and may include a stack of a first layer including the same material as the first organic insulating layer OL1, a second layer including the same material as the second organic insulating layer OL2, a third layer including the inorganic layer PVX, a fourth layer including the same material as the third organic insulating layer OL3, a fifth layer including the same material as the fourth organic insulating layer OL4, and a sixth layer including the same material as the pixel definition layer 119. The height of the third dam DAM3 may be greater than the height of the first dam DAM1 and the second dam DAM2.

The second dam DAM2 and the third dam DAM3 may share the first layer and the third layer. A third groove GV3 may be disposed between the second layer of the second dam DAM2 and the second layer of the third dam DAM3, and the second layer of the second dam DAM2 and the second layer of the third dam DAM3 may be disposed apart from each other.

The fourth dam DAM4 may be an outermost dam among the plurality of dams of the dam unit DAM. The fourth dam DAM4 may include a stack of a first layer including the same material as the first organic insulating layer OL1, a second layer including the same material as the second organic insulating layer OL2, a third layer including the inorganic layer PVX, a fourth layer including the same material as the third organic insulating layer OL3, a fifth layer including the same material as the fourth organic insulating layer OL4, a sixth layer including the same material as the pixel definition layer 119, and a seventh layer including the same material as the spacer SPC. The height of the fourth dam DAM4 may be greater than the height of the third dam DAM3.

A fourth groove GV4 may be disposed between the first layer of the third dam DAM3 and the first layer of the fourth dam DAM4, and the first layer of the third dam DAM3 and the first layer of the fourth dam DAM4 may be disposed apart from each other. A common voltage line ELVSSL may be disposed under the third dam DAM3 and the fourth dam DAM4. The common voltage line ELVSSL may be a line configured to transmit a common voltage to the light emitting elements and may be electrically connected to the opposite electrode 230.

In some embodiments, the common voltage line ELVSSL may be connected to the opposite electrode 230 through a third connection electrode CM3 and a fourth connection electrode CM4. The fourth groove GV4 may function as a contact hole connecting the common voltage line ELVSSL to the third connection electrode CM3. The common voltage line ELVSSL may be disposed on the same layer as the first source electrode S1 and/or the first drain electrode D1 of the first thin film transistor TFT1. The common voltage line ELVSSL may be disposed over the interlayer insulating layer 115. The common voltage line ELVSSL may be exposed by the fourth groove GV4, which extends thereto. The third connection electrode CM3 may be provided on the same layer and may include the same material as the first connection electrode CM1. The third connection electrode CM3 may be disposed over the first organic insulating layer OL1 and the first layer of the first to fourth dams DAM1 to DAM4.

The third connection electrode CM3 may directly contact the common voltage line ELVSSL through the fourth groove GV4. The third connection electrode CM3 may be disposed to extend from the fourth groove GV4 to the first groove GV1. The third connection electrode CM3 may directly contact the fourth connection electrode CM4 at the first groove GV1 or the side surface of the first dam DAM1. The fourth connection electrode CM4 may include the same material as the pixel electrode 210. The fourth connection electrode CM4 may directly contact the opposite electrode 230 at or around the first groove GV1.

The organic encapsulation layer 320 may be disposed up to the inner side of the third dam DAM3. However, the disclosure is not limited thereto. The organic encapsulation layer 320 may be variously modified, such as being disposed up to the inner side of the fourth dam DAM4.

The first inorganic encapsulation layer 310 and the second inorganic encapsulation layer 330 may contact each other from a partial area of the dam unit DAM and may extend through the dam unit DAM to the edge of the substrate 100. For example, the first inorganic encapsulation layer 310 and the second inorganic encapsulation layer 330 may contact each other from the upper surface of the third dam DAM3 and extend to the edge of the substrate 100.

The inorganic layer PVX included in the fourth dam DAM4 that is the outermost dam may be at least partially disposed on a side surface close to the edge of the substrate 100 among the side surfaces of the fourth dam DAM4. The first inorganic encapsulation layer 310 may directly contact the inorganic layer PVX at the side surface of the fourth dam DAM4. The second inorganic encapsulation layer 330 may directly contact the first inorganic encapsulation layer 310 at the side surface of the fourth dam DAM4. The inorganic insulating layer IL may extend to a portion of the peripheral area PA, and the inorganic layer PVX may directly contacts the inorganic insulating layer IL in the peripheral area PA.

When the inorganic layer PVX is not disposed on the side surface of the fourth dam DAM4 that is the outermost dam, the first inorganic encapsulation layer 310 and the second inorganic encapsulation layer 330 may have to contact the upper surface of the inorganic insulating layer IL extending from the display area, by a certain area or more, in order for the thin film encapsulation layer 300 to block the external air.

However, in the present embodiment, because the inorganic layer PVX is disposed on the side surface of the fourth dam DAM4, the contact area between the inorganic layers may be secured on the side surface of the fourth dam DAM4 and thus the external air may be sufficiently blocked even when the contact area with the inorganic insulating layer IL is reduced on the upper surface of the substrate 100. Accordingly, the area of the peripheral area PA may decrease. As the area of the peripheral area PA decreases, the area of the display area of the display apparatus 1 may increase.

Moreover, the first inorganic encapsulation layer 310 may clad the edge of the inorganic layer PVX on the upper surface of the substrate 100, and the second inorganic encapsulation layer 330 may clad the edge of the first inorganic encapsulation layer 310 on the upper surface of the substrate 100. By this structure, the penetration of external air into the display area may be effectively prevented.

It is illustrated that the first inorganic encapsulation layer 310 and the second inorganic encapsulation layer 330 are disposed apart from the edge of the substrate 100; however, the disclosure is not limited thereto. Unlike the illustration, the first inorganic encapsulation layer 310 and the second inorganic encapsulation layer 330 may extend to the edge of the substrate 100.

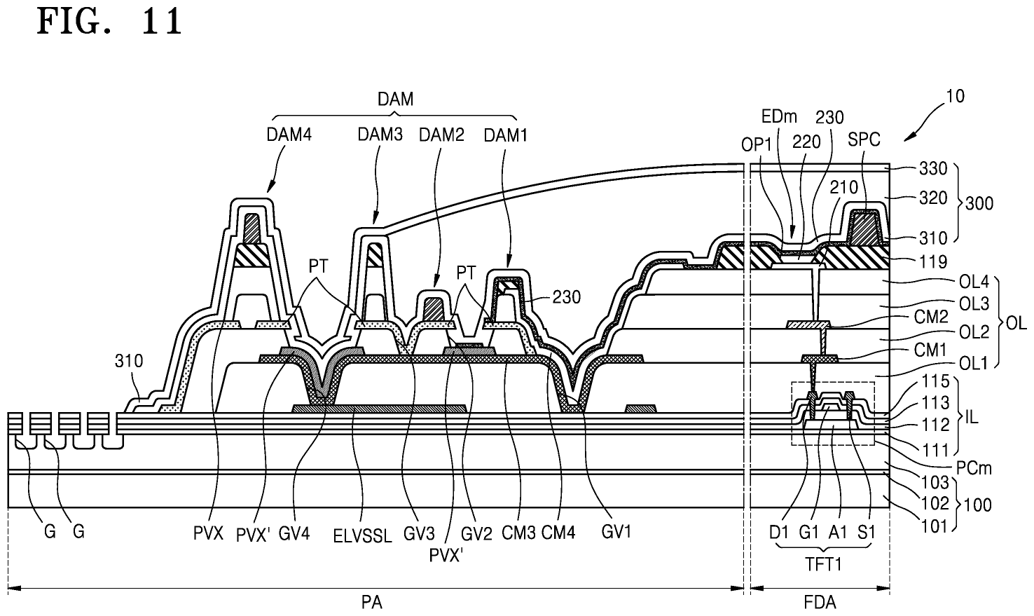

FIG. 11 is a cross-sectional view schematically illustrating a portion of a display panel according to an embodiment. In FIG. 11, like reference numerals as those in FIG. 10 denote like members, and thus, redundant descriptions thereof will be omitted for conciseness.

Referring to FIG. 11, the substrate 100 may include multiple layers. For example, the substrate 100 may include a first base layer 101, a first barrier layer 102, a second base layer 103, and a second barrier layer (not illustrated) that are sequentially stacked.

Each of the first and second base layers 101 and 103 may include a polymer resin. For example, the first and second base layers 101 and 103 may include a polymer resin such as polyethersulfone (PES), polyacrylate (PA), polyetherimide (PEI), polyethylene naphthalate (PEN), polyethylene terephthalate (PET), polyphenylene sulfide (PPS), polyimide (PI), polycarbonate (PC), cellulose triacetate (TAC), and cellulose acetate propionate (CAP). The above polymer resin may be transparent.

Each of the first barrier layer 102 and the second barrier layer may be a barrier layer for preventing the penetration of external foreign materials and may include a single layer or multiple layers including an inorganic material such as silicon nitride (SiNₓ) and/or silicon oxide (SiOₓ).

In the present embodiment, a plurality of grooves G formed by removing a portion of the inorganic insulating layer IL and the substrate 100 may be disposed between the dam unit DAM and the edge of the substrate 100 in the peripheral area PA. For example, the plurality of grooves G may be formed by connecting a hole passing through the inorganic insulating layer IL to a recess formed in the second base layer 103 of the substrate 100. The inorganic insulating layer IL may include a protrusion tip protruding into the groove G. The plurality of grooves G may be for preventing the propagation of a crack that may occur when cutting the edge of the substrate 100.

In the present embodiment, an inorganic protection layer PVX′ may be disposed over the third connection electrode CM3. The inorganic protection layer PVX′ may be formed to cover a portion of the third connection electrode CM3 in order to prevent the third connection electrode CM3 from being damaged by an etchant used to etch the pixel electrode 210. The inorganic protection layer PVX′ may include an inorganic material such as silicon nitride (SiNₓ) and/or silicon oxide (SiOₓ).

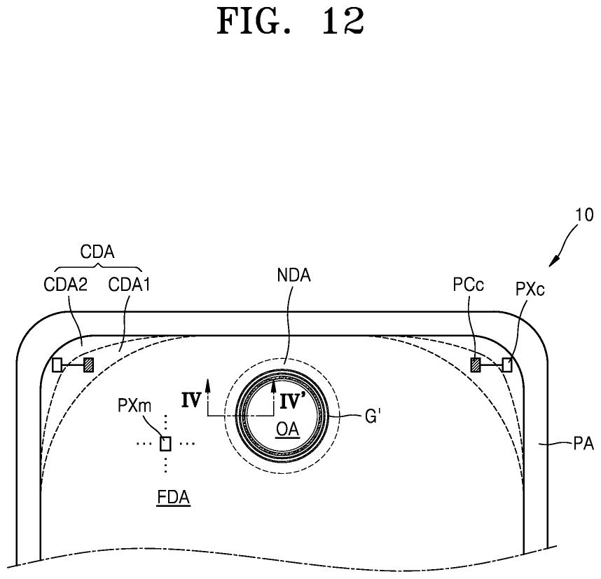

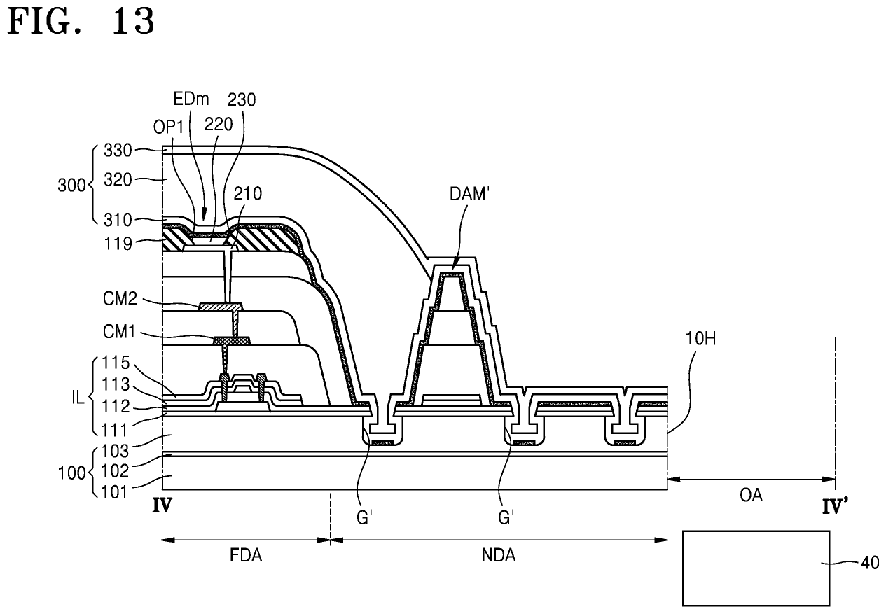

FIG. 12 is a schematic plan view illustrating a portion of a display panel 10 in an unfolded state according to an embodiment. FIG. 13 is a schematic cross-sectional view corresponding to line IV-IV′ of FIG. 12.

Referring to FIG. 12, the display panel 10 may include an opening area OA disposed inside the front display area FDA and a non-display area NDA surrounding the opening area OA.

In the plan view, the opening area OA may have various shapes such as circular shapes, elliptical shapes, polygonal shapes such as tetragonal shapes, star shapes, or diamond shapes. Also, the position of the opening area OA may be variously modified. For example, the opening area OA may be disposed at the upper center of the front display area FDA as illustrated in FIG. 12 or may be disposed at the right center or left center of the front display area FDA unlike the illustration.

As illustrated in FIG. 13, a component 40 that is an electronic element may be disposed under the display panel 10 corresponding to the opening area OA. The component 40 may include an imaging device such as a camera using infrared light or visible light. Alternatively, the component 40 may include a solar cell, a flash, an illuminance sensor, a proximity sensor, or an iris sensor. Alternatively, the component 40 may have a function of receiving sound.

Referring back to FIG. 12, the non-display area NDA may surround the opening area OA. The non-display area NDA may be an area in which a display element such as an organic light emitting diode emitting light is not disposed, and signal lines for providing signals to pixels PXm disposed around the opening area OA may pass through the non-display area NDA or an additional groove G′ may be disposed therein.

FIG. 12 illustrates that three additional grooves G′ are located in the non-display area NDA; however, the disclosure is not limited thereto. In other embodiments, one, two, or four or more grooves may be disposed in the non-display area NDA.

The additional grooves G′ may have a ring shape entirely surrounding the opening area OA in the non-display area NDA. The diameter of each of the additional grooves G′ may be greater than the diameter of the opening area OA. In the plan view, the additional grooves G′ surrounding the opening area OA may be spaced apart from each other by a certain distance.

Referring to FIG. 13, the display panel 10 (e.g., see FIG. 12) may include a first opening 10H corresponding to the opening area OA. A main light emitting element EDm may be disposed in the front display area FDA, and an opposite electrode 230 of the main light emitting element EDm may extend to the non-display area NDA.

A plurality of additional grooves G′ may be disposed in the non-display area NDA. The additional groove G′ may be formed by spatially connecting a recess formed by partially removing the second base layer 103 of the substrate 100 to a hole passing through the inorganic insulating layer IL.

The inorganic insulating layer IL may include a protrusion tip protruding toward the additional groove G′. An organic layer (not illustrated) and the opposite electrode 230 that may be included in the main light emitting element EDm may be disconnected around the additional groove G′ by the protrusion tip of the inorganic insulating layer IL.

The first inorganic encapsulation layer 310 of the thin film encapsulation layer 300 may have a better step coverage than the opposite electrode 230. Thus, the first inorganic encapsulation layer 310 may be continuously formed without being disconnected at the additional groove G′.

An additional dam DAM′ may be disposed in the non-display area NDA, and the additional dam DAM′ may block the flow of material for forming the organic encapsulation layer 320. The first inorganic encapsulation layer 310 and the second inorganic encapsulation layer 330 may contact each other between the additional dam DAM′ and the opening area OA.

The additional groove G′ formed in the non-display area NDA may be formed simultaneously with the plurality of grooves G described with reference to FIG. 11.

As described above, the display panel and the display apparatus according to the present embodiments may include a corner display area such that an image display area thereof may be extended.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope as defined by the attached claims.

What is claimed is:

1. A display panel, wherein the display panel comprises:
a substrate comprising a display area and a peripheral area around the display area;
a display element disposed in the display area;
a thin film encapsulation layer covering the display area and comprising a first inorganic encapsulation layer, an organic encapsulation layer, and a second inorganic encapsulation layer; and
a dam unit comprising a plurality of dams disposed in the peripheral area,
wherein the plurality of dams comprise an inorganic layer, the inorganic layer is at least partially disposed on a side surface of an outermost dam among the plurality of dams, and
wherein the first inorganic encapsulation layer directly contacts the inorganic layer on the side surface of the outermost dam.

2. The display panel of claim 1, wherein the inorganic layer comprises a protrusion tip protruding toward at least one groove of a plurality of grooves disposed between the plurality of dams.

3. The display panel of claim 2, wherein an opposite electrode of the display element is disconnected by the protrusion tip.

4. The display panel of claim 1, wherein the inorganic layer is disposed to extend from the side surface of the outermost dam to an upper surface of the substrate, and
the first inorganic encapsulation layer covers an edge of the inorganic layer disposed on the upper surface of the substrate.

5. The display panel of claim 1, wherein the display panel further comprises an inorganic insulating layer disposed between the substrate and the display element,
wherein the inorganic insulating layer extends to a portion of the peripheral area, and the inorganic layer directly contacts the inorganic insulating layer in the peripheral area.

6. The display panel of claim 1, wherein the display panel further comprises a plurality of grooves disposed between the dam unit and an edge of the substrate in the peripheral area.

7. The display panel of claim 1, wherein the display area comprises a front display area and a corner display area extending from a corner of the front display area, and
at least two corner light emitting elements disposed in the corner display area are connected to a pixel circuit.

8. The display panel of claim 7, wherein the corner display area comprises a first corner display area and a second corner display area, and
a driving circuit providing a scan signal is disposed in the second corner display area, and a corner light emitting element disposed in the second corner display area among the at least two corner light emitting elements is disposed to overlap the driving circuit.

9. The display panel of claim 1, wherein the substrate further comprises an opening area disposed inside a front display area and a non-display area disposed between the opening area and the front display area, and
the substrate includes a first opening corresponding to the opening area.

10. The display panel of claim 9, wherein the non-display area comprises a plurality of grooves.

11. A display apparatus, wherein the display apparatus comprises:
a cover window comprising a flat portion and a curved portion curved at a corner of the flat portion; and
a display panel disposed on a surface of the cover window and including a substrate including a display area overlapping the flat portion and a peripheral area surrounding the display area, wherein the display panel comprises:
a display element disposed in the display area;
a thin film encapsulation layer covering the display area and comprising a first inorganic encapsulation layer, an organic encapsulation layer, and a second inorganic encapsulation layer; and
a dam unit comprising a plurality of dams disposed in the peripheral area,
wherein the plurality of dams comprise an inorganic layer, the inorganic layer is at least partially disposed on a side surface of an outermost dam among the plurality of dams, and
wherein the first inorganic encapsulation layer directly contacts the inorganic layer on the side surface of the outermost dam.

12. The display apparatus of claim 11, wherein the inorganic layer comprises a protrusion tip protruding toward at least one groove of a plurality of grooves disposed between the plurality of dams.

13. The display apparatus of claim 12, wherein an opposite electrode of the display element is disconnected by the protrusion tip.

14. The display apparatus of claim 11, wherein the inorganic layer is disposed to extend from the side surface of the outermost dam to an upper surface of the substrate, and
the first inorganic encapsulation layer covers an edge of the inorganic layer disposed on the upper surface of the substrate.

15. The display apparatus of claim 11, wherein the display apparatus further comprises an inorganic insulating layer disposed between the substrate and the display element,
wherein the inorganic insulating layer extends to a portion of the peripheral area, and the inorganic layer directly contacts the inorganic insulating layer in the peripheral area.

16. The display apparatus of claim 11, wherein the display apparatus further comprises a plurality of grooves disposed between the dam unit and an edge of the substrate in the peripheral area.

17. The display apparatus of claim 11, wherein the display area comprises a front display area and a corner display area extending from a corner of the front display area, and
at least two corner light emitting elements disposed in the corner display area are connected to a pixel circuit.

18. The display apparatus of claim 17, wherein the corner display area comprises a first corner display area and a second corner display area, and
a driving circuit providing a scan signal is disposed in the second corner display area, and a corner light emitting element disposed in the second corner display area among the at least two corner light emitting elements is disposed to overlap the driving circuit.

19. The display apparatus of claim 11, wherein the display panel further comprises an opening area disposed inside a front display area and a non-display area disposed between the opening area and the front display area, and
a component corresponding to the opening area is further disposed under the display panel.

20. The display apparatus of claim 19, wherein the non-display area comprises a plurality of grooves.
